(19) United States
(12) Patent Application Publication
(10) Pub. No.: US 2026/0319003 A1
(43) Pub. Date: Oct. 15, 2026

(54) METHOD FOR DIAGNOSING IMBALANCE IN BATTERY PACK OF ELECTRIC VEHICLE AND APPARATUS THEREFOR

(71) Applicants: Hyundai Motor Company, Seoul (KR); Kia Corporation, Seoul (KR); The Industry & Academic Cooperation in Chungnam National University (IAC), Daejeon (KR)

(72) Inventors: Cheol Beom LIM, Hwaseong-Si (KR); Jong Hoon KIM, Daejeon (KR)

(21) Appl. No.: 19/343,735

(22) Filed: Sep. 29, 2025

(30) Foreign Application Priority Data
Apr. 9, 2025 (KR) 10-2025-0046328

(51) Int. Cl. G01R 31/389; B60L 58/22; G01R 31/367; G01R 31/396

(52) U.S. Cl. CPC G01R 31/389; G01R 31/367; G01R 31/396; B60L 58/22

(57) ABSTRACT

A method for diagnosing imbalance of a battery pack of an electric vehicle and an apparatus therefor are provided. The method includes receiving current and voltage signals corresponding to the battery pack from a battery management system (BMS), performing signal processing based on the received signals, extracting passive electrochemical impedance spectroscopy (PEIS) data based on the result of the signal processing, setting a threshold for imbalance cell diagnosis based on the PEIS data, and performing imbalance diagnosis of an individual cell in the battery pack based on the threshold.

### CROSS-REFERENCE TO RELATED APPLICATION

This application claims the benefit of priority to Korean Patent Application No. 10-2025-0046328, filed in the Korean Intellectual Property Office on Apr. 9, 2025, the entire contents of which are incorporated herein by reference.

### TECHNICAL FIELD

The present disclosure relates to an electric vehicle battery diagnostic technology, and more particularly, relates to technologies for deriving passive electrochemical impedance spectroscopy (PEIS) data via signal processing for a voltage and current original signal of a battery pack of an electric vehicle and diagnosing imbalance of the battery pack.

### BACKGROUND

The matters described in this Background section are only for enhancement of understanding of the background of the disclosure, and should not be taken as acknowledgment that they correspond to prior art already known to those skilled in the art.

Imbalance between cells in a battery module of an electric vehicle may be one of major problems of the electric vehicle, which may cause deterioration in performance of a battery of the electric vehicle and a safety problem.

The total capacity and energy density of the battery pack may be reduced in a cell imbalance state. This may lead to deterioration in mileage and battery performance of the electric vehicle.

Furthermore, imbalance in behavior of an individual cell in the battery pack may cause over-charging or over-discharging in a specific cell. This may act as a major factor of battery fire and damage to durability.

Thus, a battery pack imbalance diagnostic technology is used for performance and safety of the electric vehicle.

A direct current (DC)-based battery pack imbalance diagnostic algorithm may not have criteria capable of clearly determining battery pack imbalance and may simply perform diagnosing battery pack imbalance based on a voltage and resistance deviation to obtain deviation information between cells at only a corresponding specific time.

A battery pack imbalance diagnostic technology which is more accurate and reliable via a new factor capable of representing an electrochemical state as well as the voltage and the resistor deviation is considered.

An electrochemical impedance spectroscopy (EIS) diagnostic technique may have a limitation in applying a real electric vehicle (EV) due to a hardware specification limit as well as the necessity of separate equipment to generate and measure an EIS signal.

Because EIS capable of facilitating electrochemical measurement of the battery should collect data in several frequency bands, it may take a long time. Time consumption of the EIS may cause a problem in the situation in which real-time monitoring is required.

When alternating current (AC) data is used via BMS input signal processing, it is possible to ensure robustness and reliability for imbalance diagnosis.

Particularly, because the battery pack imbalance diagnostic method using AC data may be able to obtain deviation information according to a frequency domain at one time point, it is possible for the battery pack imbalance diagnostic method to ensure higher reliability than the DC scheme.

### SUMMARY

The present disclosure has been made to solve the above-mentioned problems.

According to the present disclosure, a method performed by an apparatus for a vehicle may comprise obtaining, via one or more sensors, current and voltage signals associated with a battery pack of the vehicle; processing the obtained current and voltage signals; extracting, based on the processing of the obtained current and voltage signals, passive electrochemical impedance spectroscopy (PEIS) data; setting, based on the PEIS data, a threshold for imbalance cell diagnosis; performing, based on the threshold, the imbalance cell diagnosis on an individual cell in the battery pack; and outputting a signal indicating a result of the imbalance cell diagnosis on the individual cell.

The method may further comprise determining the lower limit threshold by subtracting, from the median impedance value, a value obtained by multiplying the median absolute deviation (MAD) by a constant, and determining the upper limit threshold by adding, to the median impedance value, the value obtained by multiplying the MAD by the constant.

In the method, the outputting of the signal may comprise generating a warning message based on at least one imbalance cell being detected as the result of the imbalance cell diagnosis.

In the method, the warning message may comprise group identification information corresponding to a group containing the at least one imbalance cell, and cell identification information corresponding to the at least one imbalance cell.

According to the present disclosure, an apparatus for a vehicle may comprise a processor and a memory storing at least one instruction that, when executed by the processor communicating with the memory, is configured to cause the apparatus to obtain, via one or more sensors, current and voltage signals associated with a battery pack of the vehicle, process the obtained current and voltage signals, extract, based on the processing of the obtained current and voltage signals, passive electrochemical impedance spectroscopy (PEIS) data, set, based on the PEIS data, a threshold for imbalance cell diagnosis, perform, based on the threshold, the imbalance cell diagnosis on an individual cell in the battery pack, and output a signal indicating a result of the imbalance cell diagnosis on the individual cell.

The at least one instruction, when executed by the processor communicating with the memory, may be configured to cause the apparatus to perform a discrete wavelet transform by removing noise from at least one signal of the obtained current and voltage signals and decompose the noise-removed signal for each frequency level to obtain a time domain signal, and perform a short time Fourier transform by segmenting the time domain signal into segments to convert the time domain signal into a frequency domain signal.

The PEIS data may comprise alternating current (AC) impedance data for each frequency point in the PEIS data, and the at least one instruction, when executed by the processor communicating with the memory, may be configured to cause the apparatus to, based on a statistical technique and real part impedance data in the AC impedance data, determine the threshold.

The at least one instruction, when executed by the processor communicating with the memory, may be configured to cause the apparatus to, via the statistical technique, derive a median absolute deviation (MAD) as a median value of absolute differences, wherein each absolute difference is between an impedance value of a cell in a group of cells of the battery pack and a median impedance value of all cells in the group of cells.

The threshold may comprise a lower limit threshold and an upper limit threshold, and the at least one instruction, when executed by the processor communicating with the memory, may be configured to cause the apparatus to, based on the median impedance value and the MAD, determine the lower limit threshold and the upper limit threshold.

One value in the median impedance value may be derived for each frequency point in the PEIS data and one value in each of the absolute differences and the MAD may be derived for each cell for each frequency point in the PEIS data.

The median impedance value may be derived as a median of the real part impedance data of cells in the group for each frequency point in the PEIS data.

According to the present disclosure, a vehicle may comprise a battery pack, a processor, and a memory storing at least one instruction that, when executed by the processor communicating with the memory, is configured to cause the vehicle to receive voltage and current signals associated with a plurality of battery cells in the battery pack, process the voltage and current signals to remove noise and derive frequency-domain data associated with the plurality of battery cells, obtain, based on the frequency-domain data, passive cell impedance data, wherein the passive cell impedance data comprises real part impedance values of the plurality of battery cells, determine a median of the real part impedance values and a median of absolute deviations of the real part impedance values, set, based on the median of the real part impedance values and the median of absolute deviations, a threshold range for identifying imbalance of at least one cell of the plurality of battery cells, based on a real part impedance value of the at least one cell being outside the threshold range, identify the at least one cell as an imbalance cell, and output a warning signal indicating information of the imbalance cell.

The at least one instruction, when executed by the processor communicating with the memory, may be configured to cause the vehicle to determine the threshold range by determining an upper limit threshold by adding, to the median of the real part impedance values, a value obtained by multiplying the median of absolute deviations by a constant, and determining a lower limit threshold by subtracting, from the median of the real part impedance values, the value obtained by multiplying the median of absolute deviations by the constant.

The at least one instruction, when executed by the processor communicating with the memory, may be configured to cause the vehicle to include, in the warning signal, group identification information corresponding to a group of cells containing the imbalance cell, and cell identification information corresponding to the imbalance cell.

### BRIEF DESCRIPTION OF THE DRAWINGS

The above and other objects, features and advantages of the present disclosure will be more apparent from the following detailed description taken in conjunction with the accompanying drawings:

FIG. 1 shows an example of a configuration of a battery pack imbalance diagnostic system;

FIG. 2 shows an example of the overall battery pack imbalance diagnostic procedure;

FIG. 3 shows an example of a detailed configuration of a battery pack imbalance diagnostic apparatus;

FIG. 4 shows an example of a method for diagnosing imbalance on a cell-by-cell basis via applying a statistical technique based on real number impedance of extracted individual cell PEIS data and setting a threshold in a battery pack imbalance diagnostic apparatus;

FIG. 5 shows an example of a method for setting a threshold based on a median absolute deviation (MAD);

FIG. 6 shows an example of a method of a battery pack imbalance diagnostic apparatus; and

FIG. 7 shows an example of a computing system.

### DETAILED DESCRIPTION

Hereinafter, some examples of the present disclosure will be described in detail with reference to the exemplary drawings. In adding the reference numerals to the components of each drawing, it should be noted that the identical component is designated by the identical numerals even when they are displayed on other drawings. Further, in describing the example of the present disclosure, a detailed description of well-known features or functions will be ruled out in order not to unnecessarily obscure the gist of the present disclosure.

In describing the components of the example according to the present disclosure, terms such as first, second, “A”, “B”, (a), (b), and the like may be used. These terms are merely intended to distinguish one component from another component, and the terms do not limit the nature, sequence or order of the corresponding components. Furthermore, unless otherwise defined, all terms including technical and scientific terms used herein have the same meaning as being generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system. Although the present disclosure may apply the SAE classification standard for autonomous driving classification, other classification methods and/or algorithms may be used in one or more configurations described herein.

One or more features associated with autonomous driving control may be activated based on configured autonomous driving control setting(s) (e.g., based on at least one of: an autonomous driving classification, a selection of an autonomous driving level for a vehicle, etc.). Based on one or more features (e.g., feature of imbalance diagnosis in battery packs using PEIS-based statistical thresholding) described herein, an operation of the vehicle may be controlled. The vehicle control may include various operational controls associated with the vehicle (e.g., autonomous driving control, sensor control, braking control, braking time control, acceleration control, acceleration change rate control, alarm timing control, forward collision warning time control, etc.).

One or more auxiliary devices (e.g., engine brake, exhaust brake, hydraulic retarder, electric retarder, regenerative brake, etc.) may also be controlled, for example, based on one or more features (e.g., feature of imbalance diagnosis in battery packs using PEIS-based statistical thresholding) described herein.

One or more communication devices (e.g., a modem, a network adapter, a radio transceiver, an antenna, etc., that is capable of communicating via one or more wired or wireless communication protocols, such as Ethernet, Wi-Fi, near-field communication (NFC), Bluetooth, Long-Term Evolution (LTE), 5G New Radio (NR), vehicle-to-everything (V2X), etc.) may also be controlled, for example, based on one or more features (e.g., feature of imbalance diagnosis in battery packs using PEIS-based statistical thresholding) described herein.

Minimum risk maneuver (MRM) operation(s) may also be controlled, for example, based on one or more features (e.g., feature of imbalance diagnosis in battery packs using PEIS-based statistical thresholding) described herein. A minimal risk maneuvering operation (e.g., a minimal risk maneuver, a minimum risk maneuver) may be a maneuvering operation of a vehicle to minimize (e.g., reduce) a risk of collision with surrounding vehicles in order to reach a lowered (e.g., minimum) risk state. A minimal risk maneuver may be an operation that may be activated during autonomous driving of the vehicle when a driver is unable to respond to a request to intervene. During the minimal risk maneuver, one or more processors of the vehicle may control a driving operation of the vehicle for a set period of time.

Biased driving operation(s) may also be controlled, for example, based on one or more features (e.g., feature of imbalance diagnosis in battery packs using PEIS-based statistical thresholding) described herein. A driving control apparatus may perform a biased driving control. To perform a biased driving, the driving control apparatus may control the vehicle to drive in a lane by maintaining a lateral distance between the position of the center of the vehicle and the center of the lane. For example, the driving control apparatus may control the vehicle to stay in the lane but not in the center of the lane. The driving control apparatus may identify or determine a biased target lateral distance for biased driving control. For example, a biased target lateral distance may comprise an intentionally adjusted lateral distance that a vehicle may aim to maintain from a reference point, such as the center of a lane or another vehicle, during maneuvers such as lane changes. This adjustment may be made to improve the vehicle's stability, safety, and/or performance under varying driving conditions, etc. For example, during a lane change, the driving control system may bias the lateral distance to keep a safer gap from adjacent vehicles, considering factors such as the vehicle's speed, road conditions, and/or the presence of obstacles, etc.

One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on one or more features (e.g., feature of imbalance diagnosis in battery packs using PEIS-based statistical thresholding) described herein. An operation control for autonomous driving of the vehicle may include various driving control of the vehicle by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.).

An autonomous driving activation/deactivation operation may be controlled based on one or more features (e.g., feature of imbalance diagnosis in battery packs using PEIS-based statistical thresholding) described herein. In particular, a diagnostic control apparatus may determine an imbalance status for the battery pack from PEIS data (e.g., using module-median and median absolute deviation (MAD) thresholds for the real-part impedance at multiple frequency points) and gate autonomous driving accordingly. When the imbalance status is normal (e.g., all cells within upper/lower impedance thresholds), autonomous driving may be enabled. When the imbalance status is cautionary (e.g., one or more cells marginally outside thresholds at limited frequency points or persisting for a short time window), autonomous driving may be restricted (e.g., speed/acceleration limits, route constraints, or reduced feature set), and a driver takeover request may be prepared. When the imbalance status is critical (e.g., a cell exceeds an upper/lower threshold by a set multiple of MAD across several frequency points or samples), autonomous driving may be deactivated and a minimal risk maneuver initiated (e.g., controlled deceleration, lane-keeping to shoulder, or safe stop), while issuing a warning that includes module and cell identification information.

The present disclosure relates to a technique for diagnosing imbalance in a battery pack of an electric vehicle. In this technique, voltage and current signals from a battery management system (BMS) are processed using discrete wavelet transform (DWT) to remove noise and decompose the signals into frequency levels, and short time Fourier transform (STFT) to convert the time-domain signals into frequency-domain signals. From the processed data, passive cell impedance data is obtained for each cell without using separate impedance spectroscopy equipment. The real part impedance values from the passive cell impedance data are analyzed using a statistical method, such as median absolute deviation (MAD), to determine upper and lower threshold values for each frequency point in the passive cell impedance data. The frequency point may be a specific frequency value. Individual cells having impedance values outside of the determined thresholds may be classified as imbalance cells. When an imbalance cell is detected, a warning message identifying a corresponding module (e.g., a group of cells containing the imbalance cell) and cell may be generated and output to a vehicle display or alert system. This approach enables real-time, cost-efficient, and reliable imbalance diagnosis, while also providing information on battery health and safety conditions.

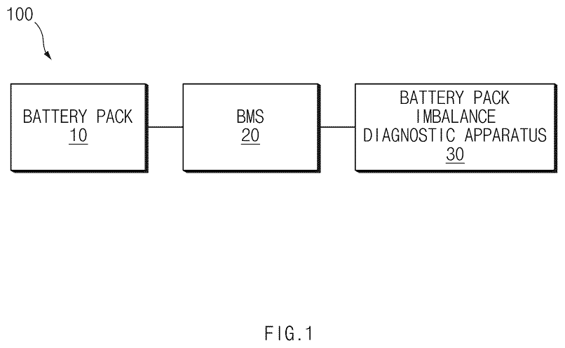

Hereinafter, examples of the present disclosure will be described in detail with reference to FIGS. 1 to 7.

FIG. 1 shows an example of a configuration of an electric vehicle battery diagnostic system according to an example of the present disclosure.

Referring to FIG. 1, an electric vehicle battery diagnostic system 100 may be roughly configured to include a battery pack 10, a battery management system (BMS) 20, and a battery pack imbalance diagnostic apparatus 30 (e.g., implemented as a dedicated hardware device, an integrated control unit, or a software module running on an existing ECU).

The battery pack 10 may be in a final form of a battery located in an electric vehicle. The pack may be formed by binding several module (e.g., front-mounted modules, rear-mounted modules, or underfloor modules)s. Each module may be configured to include several battery cells (e.g., cylindrical, prismatic, or pouch-type cells).

The module (e.g., a group of cells bundled together) is a battery assembly formed by binding a certain number of battery cells and inserting them into a frame to protect them from an external impact, heat, vibration, moisture, dust, or other environmental factors (e.g., road debris, humidity, or temperature cycling).

The battery cell may be a basic unit of the battery, which is capable of using electric energy for charging/discharging, and may be implemented by inserting a cathode, an anode, a separator, and an electrolyte into an aluminum case (or other suitable casing materials, such as steel or laminated polymer).

The BMS 20 may manage parameters such as a temperature, a voltage, a current, or the like for the battery module (e.g., by controlling cooling fans, pumps, or heaters, and adjusting charging or discharging rates).

The BMS 20 according to an example may be mounted into the battery pack 10. Various control and protection systems, such as a cooling device (e.g., liquid cooling plates, air ducts, or refrigerant-based systems), may be provided in the battery pack 10.

The BMS 20 according to an example may detect a voltage difference between battery cells and may perform cell balancing (e.g., passive balancing using resistors or active balancing using inductors or capacitors), when detecting voltage imbalance between cells.

In general, when the voltage difference between battery cells is not uniformly maintained, overload may more easily be loaded onto one specific cell, increasing fire risk. Thus, accurately and quickly detecting voltage imbalance between battery cells is important to ensure safety of an electric vehicle (e.g., preventing thermal runaway, avoiding reduced driving range, or prolonging battery life).

The BMS 20 may monitor voltages and currents of individual cells in the battery pack 10 during vehicle operation and may generate and transmit voltage and current signals to the battery pack imbalance diagnostic apparatus 30 for real-time or periodic analysis.

The battery pack imbalance diagnostic apparatus 30 may perform signal processing for the voltage and current signals received from the BMS 20 to derive passive electrochemical impedance spectroscopy (PEIS) data for each battery cell. Herein, the voltage and current signals received from the BMS 20 may be a direct current (DC) signal and the signal processing may include discrete wavelet transform (DWT) and short time Fourier transform (STFT).

The PEIS according to the present disclosure has an advantage capable of extracting a cell level of EIS data via vehicle BMS voltage/current signal processing without requiring a separate EIS device (e.g., laboratory-grade frequency response analyzers).

The DWT is a transform for decomposing a given signal into several sets. Herein, each set is a time series of coefficients describing a change in time of a signal in a corresponding frequency band. The DWT is a mathematical process for quantifying how much energy is included in a specific frequency band in a specific time in the signal (e.g., detecting noise spikes, transient events, or gradual drifts).

In other words, the DWT may be implemented as logic for removing noise included in the voltage and current signals input from the BSM 20 and decomposing data for each frequency level to extract a time domain signal for subsequent analysis.

The STFT is one of the Fourier transforms for transforming a time domain signal into a frequency domain signal, which may be used to determine a sinusoidal frequency and a phase component of a local section of the signal, when the signal changes over time. Particularly, the STFT may be implemented as logic for dividing a long time domain signal into shorter segments, each of which has the same length, and individually performing Fourier transform for each short segment (e.g., enabling localized frequency analysis during vehicle acceleration, braking, or charging events).

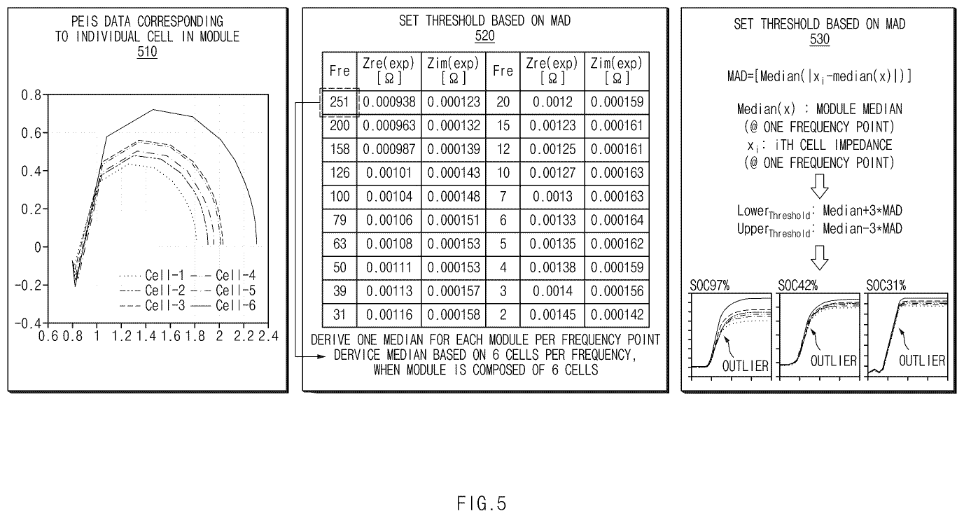

The battery pack imbalance diagnostic apparatus 30 may derive PEIS data for an individual cell in the module (e.g., a group of cells) via the above-mentioned signal processing and may apply a median absolute deviation (MAD) which is a statistical technique to the derived PEIS data to set a threshold for imbalance diagnosis for each battery cell. The method for setting the threshold based on the MAD will be described in detail below with reference to FIG. 5 which will be described below.

The battery pack imbalance diagnostic apparatus 30 according to an example may apply only a real part impedance component in the derived PEIS data to the MAD. This is because the real part component represents a resistance component according to a frequency domain (e.g., related to ohmic resistance, electrolyte conductivity, or contact resistance).

The battery pack imbalance diagnostic apparatus 30 may compare real part impedance of the battery cell with the threshold to detect and diagnose an imbalance cell.

The battery pack imbalance diagnostic apparatus 30 according to an example may be mounted into the battery pack 10. The battery pack imbalance diagnostic apparatus 30 according to another example may be integrally implemented with the BMS 20.

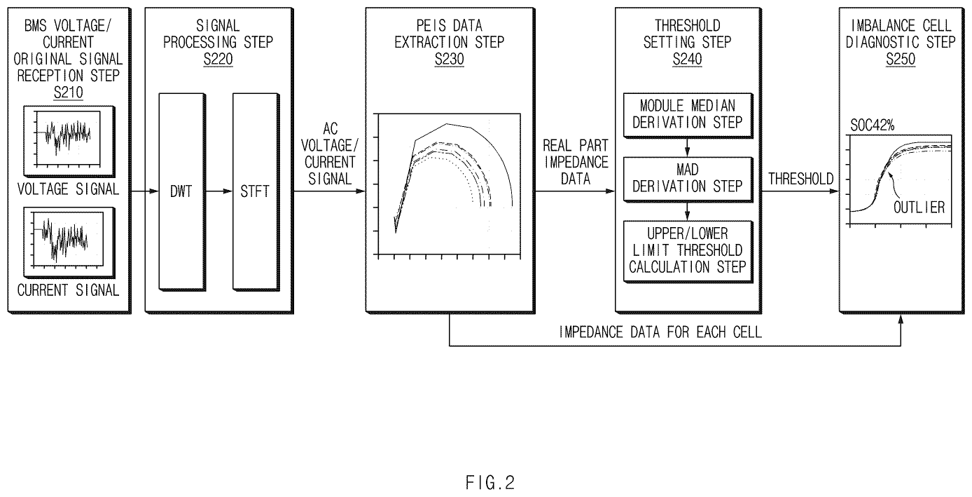

FIG. 2 shows an example of the overall battery pack imbalance diagnostic procedure according to an example of the present disclosure.

Referring to FIG. 2, the battery pack imbalance diagnostic procedure may include a BMS voltage/current original signal reception step S210, a signal processing step S220 (e.g., filtering noise, separating frequency bands, or converting signals into a usable analysis format), a PEIS data extraction step S230 (e.g., deriving real and imaginary impedance components for each cell at multiple frequencies), a threshold setting step S240 (e.g., determining upper and lower impedance thresholds based on median and median absolute deviation values for cells in the same module), and an imbalance cell diagnostic step S250 (e.g., flagging a cell as imbalanced if its impedance exceeds the thresholds at one or more frequencies).

In the BMS voltage/current original signal reception step S210, a battery pack imbalance diagnostic apparatus 30 may receive a voltage and current original signal from a BMS 20. Herein, the voltage and current original signal may be a DC signal (e.g., sampled at 10 Hz, 100 Hz, 1 kHz, or other rates, etc.).

In the signal processing step S220, the battery pack imbalance diagnostic apparatus 30 may perform discrete wavelet transform (DWT) (e.g., using Daubechies, Symlet, or Coiflet wavelets) for removing a noise component included in the received original signal (e.g., noise caused by inverter switching, electromagnetic interference, or sensor error) and decomposing data for each frequency level (e.g., low, mid, or high frequency bands) to extract a time domain signal.

Furthermore, in the signal processing step S220, the battery pack imbalance diagnostic apparatus 30 may perform short time Fourier transform (STFT) (e.g., using a Hamming or Hann window) for extracting AC impedance data for each frequency (e.g., 1 Hz, 10 Hz, or 100 Hz) based on DC voltage and current signal data of an individual cell in a battery pack 10 via transformation of the time domain signal into a frequency domain signal.

In the PEIS data extraction step S230, the battery pack imbalance diagnostic apparatus 30 may extract PEIS data for each individual cell frequency point in the battery pack 10 (e.g., impedance values at 0.1 Hz, 1 Hz, and 10 Hz for a given cell). Herein, the individual cell frequency point may be plural in number (e.g., multiple discrete measurement frequencies for each cell). As an example, the number of the individual cell frequency points may be, but is not limited to, 20 in total (e.g., 10, 20, 40, or 100 points, etc.). The PEIS data according to an example may be extracted for each cell in a module and may include real part impedance data and imaginary part impedance data.

In the threshold setting step S240, the battery pack imbalance diagnostic apparatus 30 may apply a statistical technique based on the real part impedance data in the PEIS data extracted for each individual cell (e.g., resistance values at specific frequencies such as 0.1 Hz, 1 Hz, or 10 Hz) to set a threshold. As an example, a median absolute deviation (MAD) may be applied to the statistical technique (e.g., calculating a median impedance value for cells in a module and determining deviations from the median to define upper and lower threshold limits). The threshold for imbalance cell diagnosis may be determined based on the module median and the MAD and may include an upper limit threshold and a lower limit threshold (e.g., computed as module median ±K×MAD where K is a constant, etc.).

As in an equation below, the MAD according to an example may be defined as a median value of absolute differences, where each absolute difference is between an impedance value Xᵢ of an individual i-th cell in X-th module and a median impedance value, median(x), of all cells in the X-th module.

MAD=[Median(|xᵢ−median(x)|)]

For example, if a module contains cells with impedance values of 5.1, 5.3, 5.5, and 6.0 mΩ, median(x) would be 5.4 mΩ, and the absolute deviations would be 0.3, 0.1, 0.1, and 0.6 mΩ. The MAD is then calculated as the median of these deviations (e.g., 0.2 mΩ in this case).

The battery pack imbalance diagnostic apparatus 30 may calculate a module median based on impedance estimated based on an individual cell in the battery pack 10 for each frequency point. Herein, one module median may be derived per frequency point.

The battery pack imbalance diagnostic apparatus 30 may calculate an absolute deviation between the calculated module median for each frequency point and individual cell impedance in the module (e.g., the difference between a 1 Hz module median and the 1 Hz impedance value of each cell in that module). Herein, one absolute deviation may be derived for each cell per frequency point.

The battery pack imbalance diagnostic apparatus 30 may calculate an MAD based on the median of the absolute deviation (e.g., aggregating all absolute deviations for cells in the same module at a given frequency and determining their median). Herein, one MAD may be derived for each cell per frequency point.

A lower limit threshold Lower_{Threshold} and an upper limit threshold Upper_{Threshold} may be determined by equations below.

Lower_{Threshold}=Module Median−3*MAD

Upper_{Threshold}=Module Median−3*MAD

The battery pack imbalance diagnostic apparatus 30 according to an example may apply the MAD based on real part impedance data for each frequency point in the PEIS data extracted for each cell in the battery pack 10 (e.g., values measured at low frequencies such as 0.1 Hz, mid-range frequencies such as 10 Hz, or high frequencies such as 1 kHz, etc.).

In the imbalance cell diagnostic step 250, the battery pack imbalance diagnostic apparatus 30 may classify impedance data of a given cell, which deviates from the set upper/lower limit threshold (e.g., more than 15% above the upper limit, more than 10% below the lower limit, or exceeding an absolute impedance limit such as 50 mΩ, etc.), as abnormal data and may diagnose the cell as an imbalance cell.

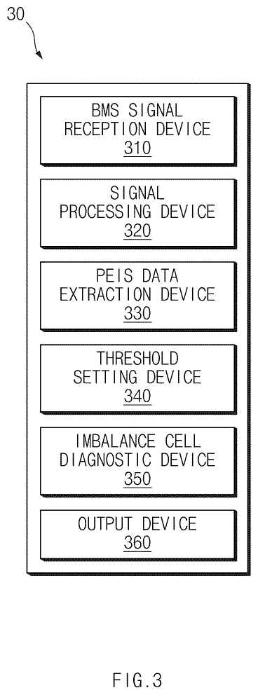

FIG. 3 shows an example of a detailed configuration of a battery pack imbalance diagnostic apparatus according to an example of the present disclosure.

Referring to FIG. 3, a battery pack imbalance diagnostic apparatus 30 may be configured to include a BMS signal reception device 310, a signal processing device 320, a PEIS data extraction device 330, a threshold setting device 340, an imbalance cell diagnostic device 350, and an output device 360 (e.g., a display unit, a wireless transmitter, a data logger, or a vehicle control interface, etc.).

The BMS signal reception device 310 may receive a voltage and current original signal from a BMS 20. Herein, the voltage and current original signal may be a DC signal (e.g., steady-state pack voltage of 350 V, continuous current draw of 50 A, or other non-AC measurement signals, etc.).

The signal processing device 320 may perform discrete wavelet transform (DWT) for removing a noise component included in the received original signal (e.g., electromagnetic interference, sensor drift, or random fluctuations, etc.) and decomposing data for each frequency level to extract a time domain signal and may further perform short time Fourier transform (STFT) for extracting AC impedance data for each frequency based on DC voltage and current signal data of an individual cell in the battery pack 10 via transformation of the time domain signal into a frequency domain signal (e.g., converting transient voltage spikes into corresponding frequency peaks, etc.).

The PEIS data extraction device 330 may extract PEIS data for each individual cell frequency point in the battery pack 10. Herein, the individual cell frequency point may be plural in number. As an example, the number of the individual cell frequency points may be, but is not limited to, 20 in total (e.g., frequency points at 0.01 Hz, 0.1 Hz, 1 Hz, or 10 Hz, etc.). The PEIS data according to an example may be extracted for each cell in a module and may include real part impedance data and imaginary part impedance data (e.g., representing resistive and reactive components, respectively).

The threshold setting device 340 may apply a statistical technique based on the real part impedance data in the PEIS data extracted for each individual cell to set a threshold. As an example, a median absolute deviation (MAD) may be applied to the statistical technique. The threshold for imbalance cell diagnosis may be determined based on the module median and the MAD and may include an upper limit threshold and a lower limit threshold (e.g., ±15% of the module median impedance value, etc.).

As in an equation below, the MAD according to an example may be defined as a median value of absolute differences between an impedance value Xᵢ of an individual i-th cell in the X-th module and a median impedance value, median(x), of all cells in the X-th module.

MAD=[Median(|xᵢ−median(x)|)]

The threshold setting device 340 may calculate a module median based on impedance values estimated for each individual cell in the battery pack 10 for each frequency point of the PEIS measurement data (e.g., 5 Hz, 10 Hz, 20 Hz, or 50 Hz, etc.). Herein, one module median may be derived per frequency point.

The threshold setting device 340 may calculate an absolute deviation between the calculated module median for each frequency point and the impedance value of an individual cell in the module. Herein, one absolute deviation may be derived for each cell at each frequency point of the PEIS measurement data.

The threshold setting device 340 may calculate the MAD based on the median of the absolute deviation. Herein, one MAD may be derived for each cell per frequency point.

A lower limit threshold (Lower_{Threshold}) and an upper limit threshold (Upper_{Threshold}) may be determined by equations below.

Lower_{Threshold}=Module Median−3*MAD

Upper_{Threshold}=Module Median−3*MAD

The threshold setting device 340 according to an example may apply the MAD based on real part impedance data for each frequency point in the PEIS data extracted for each cell in the battery pack 10 to set a threshold (e.g., using resistance values at specific frequencies rather than complex impedance values).

The imbalance cell diagnostic device 350 may classify impedance data, which deviates from the set upper/lower limit threshold, as abnormal data and may diagnose an imbalance cell (e.g., a cell with unusually high internal resistance or a cell with significantly lower impedance than its peers).

When an imbalance cell is diagnosed, the output device 360 may generate a warning alarm message indicating that battery pack imbalance is detected and may transmit the generated warning alarm message to an output device provided in a vehicle (e.g., a dashboard cluster, infotainment display, or maintenance log system).

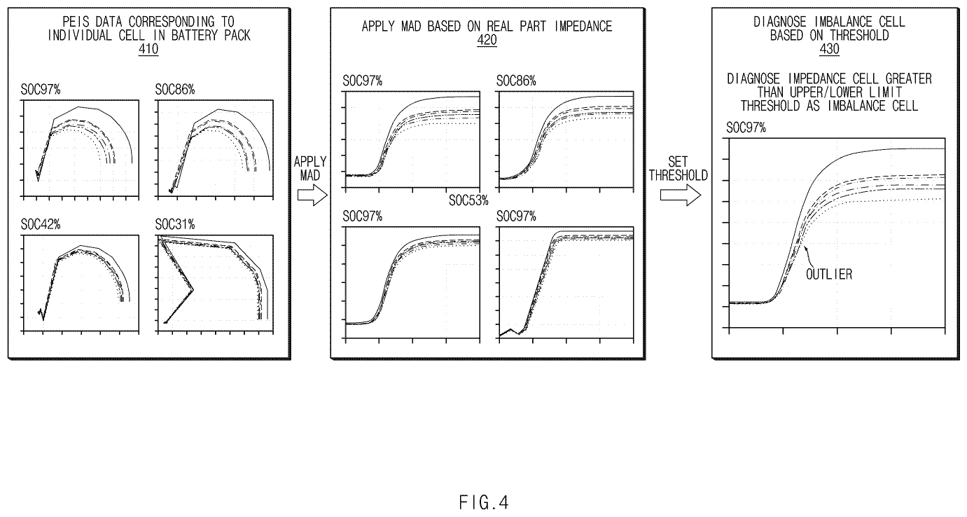

FIG. 4 shows an example of a process of applying a statistical technique based on real number impedance of extracted individual cell PEIS data to set a threshold and diagnosing an imbalance cell in a battery pack imbalance diagnostic apparatus according to an example of the present disclosure.

Referring to FIG. 4, a battery pack imbalance diagnostic apparatus 30 may apply an MAD based on real part impedance data for each frequency point in individual cell PEIS data extracted via signal processing for a voltage/current signal received from a BMS 20 to set an upper/lower limit threshold for imbalance cell diagnosis (e.g., setting a ±3×MAD range around a module median) and may diagnose a cell, for which an impedance value deviates from the set upper/lower limit threshold of which is detected, as an imbalance cell (e.g., a cell with high internal resistance, degraded capacity, or abnormal electrochemical behavior, etc.).

FIG. 5 shows an example of a procedure for setting a threshold based on a median absolute deviation (MAD) according to an example of the present disclosure (e.g., for detecting voltage imbalance, identifying abnormal impedance values, or triggering a battery safety alert, etc.).

As shown in reference numeral 510 of FIG. 5, a battery pack imbalance diagnostic apparatus 30 may extract PEIS data corresponding to an individual cell in a module.

Referring to reference numeral 520, the PEIS data may include impedance data of a real part component and impedance data of an imaginary part component for an individual cell in a battery pack for each frequency point (e.g., 5 Hz, 10 Hz, 20 Hz, or 50 Hz, etc.) of the PEIS measurement data. Herein, one median may be derived for each module per frequency point. As an example, when the module is composed of 6 cells, a module median may be derived based on impedance data of the 6 cells at each frequency point of the PEIS measurement data.

Referring to reference numeral 530, as in an equation below, the MAD may be calculated as a median value of absolute deviations between an impedance value Xᵢ of an individual i-th cell in the X-th module and a median impedance value, median(x), of all cells in the X-th module.

MAD=[Median(|xᵢ−median(x)|)]

Herein, the impedance value Xᵢ of the individual i-th cell in the X-th module and the median impedance value, median(x), of all cells in the X-th module may be derived for each frequency point of the PEIS measurement data.

The upper/lower limit threshold may be calculated using equations below based on the one module median impedance value and the one MAD value, which are derived for all cells in the one module at each frequency point.

Lower_{Threshold}=Module Median−3*MAD

Upper_{Threshold}=Module Median−3*MAD

The battery pack imbalance diagnostic apparatus 30 may apply the MAD based on real part impedance data (e.g., resistive impedance at a given frequency) for each frequency point in the PEIS data extracted for each cell in the battery pack 10 to set a threshold.

The battery pack imbalance diagnostic apparatus 30 may classify cell impedance measurements data, which deviates from the set upper/lower limit threshold, as abnormal data and may diagnose the corresponding cell as an imbalance cell.

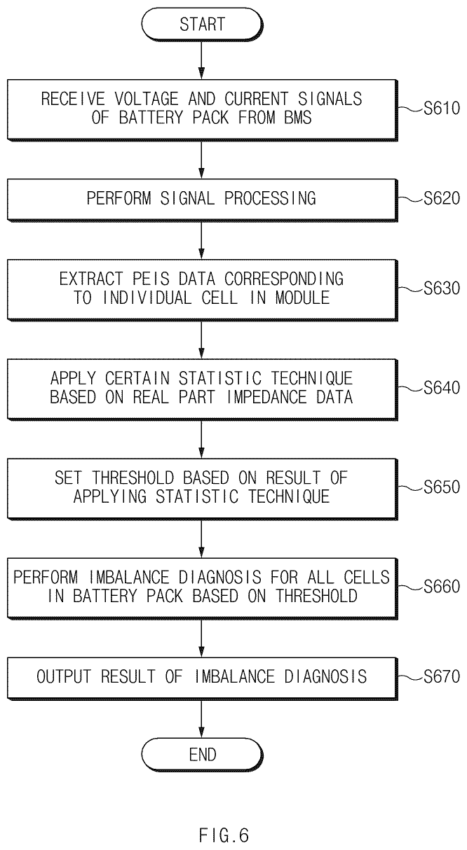

FIG. 6 shows an example of a method of operating a battery pack imbalance diagnostic apparatus according to an example of the present disclosure.

Referring to FIG. 6, in S610, a battery pack imbalance diagnostic apparatus 30 may receive voltage and current signals of a battery pack 10 from a BMS 20 (e.g., during charging, discharging, or regenerative braking, etc.).

In S620, the battery pack imbalance diagnostic apparatus 30 may perform signal processing for the received voltage and current signals. Herein, the signal processing may include the DWT and the STFT, which are described above, to remove noise and extract cell-specific frequency data (e.g., low-frequency impedance for SoH estimation or high-frequency impedance for fault detection, etc.).

In S630, the battery pack imbalance diagnostic apparatus 30 may extract PEIS data corresponding to an individual cell in a module for multiple frequency points.

In S640, the battery pack imbalance diagnostic apparatus 30 may apply a statistical technique based on real part impedance data in the extracted PEIS data. The statistical technique according to an example may include an MAD (e.g., for detecting outliers in cell impedance distributions).

In S650, the battery pack imbalance diagnostic apparatus 30 may set a threshold for diagnosing an imbalance cell based on the result of applying the statistical technique. Herein, the threshold may include an upper limit threshold and a lower limit threshold to define the acceptable impedance range for each frequency point.

In S660, the battery pack imbalance diagnostic apparatus 30 may perform imbalance diagnosis of all cells in the battery pack 10 based on the set threshold by comparing each cell's real part impedance value with the acceptable range.

In S670, the battery pack imbalance diagnostic apparatus 30 may output the result of the imbalance diagnosis. As an example, when there is an imbalance cell in the battery pack 10 as a result of the imbalance diagnosis, the battery pack imbalance diagnostic apparatus 30 may generate a certain warning alarm message including the result of the battery pack imbalance diagnosis and may transmit the generated warning alarm message to an output device provided in a vehicle. Herein, the output device may include, but is not limited to, at least one of a cluster, an audio video navigation (AVN) system, a head-up display, or a speaker (e.g., emitting a chime, flashing a warning icon, or displaying detailed cell/module status). The result of the battery pack imbalance diagnosis according to an example may include module identification information of a module including an imbalance cell and cell identification information of a cell in the module (e.g., “Module 3-Cell 5” or “Module 1-Cell 2,” etc.).

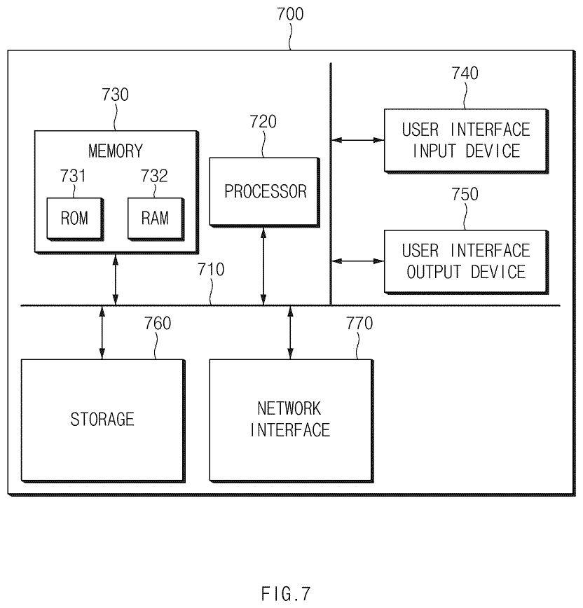

FIG. 7 shows an example of a computing system according to an example of the present disclosure.

Referring to FIG. 7, a computing system 700 may include at least one processor 720, a memory 730, a user interface input device 740, a user interface output device 750, a storage 760, and a network interface 770, which are connected with each other via a bus 710 (e.g., a high-speed serial bus or a parallel bus depending on design requirements).

The network interface 770 according to an example may perform at least one of diagnostic communication, inter-vehicle communication, and(or) communication with a server outside a vehicle (e.g., remote diagnostics server, fleet management platform, or over-the-air update server, etc.). The network interface 770 may interwork with a BMS 20, a navigation system, for example, an audio, video and navigation (AVN) system, a cluster, or the like via in-vehicle communication protocols (e.g., CAN, LIN, FlexRay, MOST, or Ethernet, etc.). The in-vehicle communication according to an example may include, but is not limited to, at least one of controller area network (CAN) communication, local interconnect network (LIN) communication, FlexRay communication, media oriented systems transport (MOST) communication, or Ethernet communication.

The processor 720 may be a central processing unit (CPU) or a semiconductor device that processes instructions stored in the memory 730 and/or the storage 760 (e.g., a microcontroller, system-on-chip (SoC), or digital signal processor (DSP), etc.). The memory 730 and the storage 760 may include various types of volatile or non-volatile storage media. For example, the memory 730 may include a ROM (Read Only Memory) 731 and a RAM (Random Access Memory) 732 (e.g., SRAM or DRAM).

Thus, the operations of the method or the algorithm described in connection with the examples disclosed herein may be embodied directly in hardware or a software module executed by the processor 720, or in a combination thereof. The software module may reside on a storage medium (i.e., the memory 730 and/or the storage 760) such as a RAM, a flash memory, a ROM, an EPROM, an EEPROM, a register, a hard disc, a removable disk, and a CD-ROM (e.g., storing executable code for the MAD threshold calculation or PEIS data processing).

The exemplary storage medium may be coupled to the processor 720. The processor 720 may read out information from the storage medium and may write information in the storage medium. Alternatively, the storage medium may be integrated with the processor 720. The processor 720 and the storage medium may reside in an application specific integrated circuit (ASIC) (e.g., a custom-designed battery diagnostic control ASIC). The ASIC may reside in the control unit in the vehicle. Alternatively, the processor 720 and the storage medium may reside as separate components in the electric vehicle (e.g., housed within a BMS enclosure or a dedicated diagnostic ECU).

As an example, the computing system 700 may be implemented to perform at least one function and method disclosed in FIGS. 1 to 6 described above and may be applied to at least one of the components of the above-mentioned electric vehicle battery diagnostic system 100 (e.g., integrated into the BMS, a telematics control unit, or an external service tool).

An aspect of the present disclosure provides a method for diagnosing imbalance of a battery pack of an electric vehicle and an apparatus therefor.

Another aspect of the present disclosure provides an electric vehicle battery pack diagnostic technology for extracting real-time AC impedance for each frequency via signal processing for a voltage and current original signal input from a BMS and diagnosing battery pack imbalance on a cell-by-cell basis based on real part impedance of passive electrochemical impedance spectroscopy (PEIS) of an individual cell in a battery pack.

Another aspect of the present disclosure provides a method for diagnosing imbalance of a battery pack based on BMS signal processing impedance to perform battery pack imbalance diagnosis by using AC impedance information extracted via signal processing for a voltage and current original signal input from a BMS as one index and obtain various pieces of information, such as a state of health (SOH) and a safety deviation in the battery module and an apparatus therefor.

Another aspect of the present disclosure provides a method for diagnosing imbalance of a battery pack based on BMS signal processing impedance to apply a statistical technique based on real part impedance of PEIS, which is AC impedance extracted via BMS input signal processing even without having separate EIS equipment, to diagnose imbalance in the battery pack and an apparatus therefor.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a method for diagnosing imbalance in a battery pack of an electric vehicle may include receiving current and voltage signals corresponding to the battery pack from a battery management system (BMS), performing signal processing based on the received signals, extracting passive electrochemical impedance spectroscopy (PEIS) data based on the result of the signal processing, setting a threshold for imbalance cell diagnosis based on the PEIS data, and performing imbalance diagnosis of an individual cell in the battery pack based on the threshold.

As an example, the performing of the signal processing may include a discrete wavelet transform step of removing noise from a received direct current (DC) signal and decomposing data for each frequency level to extract a time domain signal and a short time Fourier transform step of segmenting the time domain signal into short segments to convert the time domain signal into a frequency domain signal.

As an example, the PEIS data may include alternating current (AC) impedance data for each frequency point. The threshold may be determined by applying a statistical technique based on real part impedance data in the AC impedance data.

As an example, a median absolute deviation (MAD) which is a median of an absolute deviation between a module median of an x-th module in the battery pack and an impedance observation of an ith cell in the xth module may be derived via the statistical technique.

As an example, the threshold may include a lower limit threshold and an upper limit threshold. The lower limit threshold and the upper limit threshold may be determined based on the module median and the MAD.

As an example, one value in the module median may be derived per frequency point and one value in each of the absolute deviation and the MAD may be derived for each cell per frequency point.

As an example, the module median may be derived as a median of the real part impedance data of all cells included in the module per frequency point.

As an example, the lower limit threshold may be calculated by subtracting a value obtained by multiplying the MAD by a certain constant from the module median. The upper limit threshold may be calculated by adding the module median and the value obtained by multiplying the MAD by the certain constant.

As an example, the method may further include generating and outputting a certain warning alarm message based on that at least one abnormal cell is detected as a result of the imbalance diagnosis of individual cells in the battery pack.

As an example, the warning alarm message may include module identification information corresponding to the abnormal cell and cell identification information corresponding to the abnormal cell.

According to another aspect of the present disclosure, a computing device for diagnosing imbalance in a battery pack of an electric vehicle may include a processor that executes instructions and a memory storing the instructions. The instructions may be implemented to receive current and voltage signals corresponding to the battery pack from a battery management system (BMS), perform signal processing based on the received signals, extract passive electrochemical impedance spectroscopy (PEIS) data based on the result of the signal processing, set a threshold for imbalance cell diagnosis based on the PEIS data, and perform imbalance diagnosis of an individual cell in the battery pack based on the threshold.

As an example, the signal processing may include discrete wavelet transform for removing noise from a received DC signal and decomposing data for each frequency level to extract a time domain signal and short time Fourier transform for segmenting the time domain signal into short segments to convert the time domain signal into a frequency domain signal.

As an example, the PEIS data may include AC impedance data for each frequency point. The processor may apply a statistical technique based on real part impedance data in the AC impedance data to determine the threshold.

As an example, the processor may derive a median absolute deviation (MAD) which is a median of an absolute deviation between a module median of an xth module in the battery pack and an impedance observation of an ith cell in the xth module via the statistical technique.

As an example, the threshold may include a lower limit threshold and an upper limit threshold. The processor may determine the lower limit threshold and the upper limit threshold based on the module median and the MAD.

As an example, one value in the module median may be derived per frequency point and one value in each of the absolute deviation and the MAD may be derived for each cell per frequency point.

As an example, the module median may be derived as a median of the real part impedance data of all cells included in the module per frequency point.

As an example, the lower limit threshold may be calculated by subtracting a value obtained by multiplying the MAD by a certain constant from the module median. The upper limit threshold may be calculated by adding the module median and the value obtained by multiplying the MAD by the certain constant.

As an example, the processor may generate and output a certain warning alarm message based on that at least one abnormal cell is detected as a result of the imbalance diagnosis of individual cells in the battery pack.

As an example, the warning alarm message may include module identification information corresponding to the abnormal cell and cell identification information corresponding to the abnormal cell.

The present technology may provide the method for diagnosing the imbalance of the battery pack of the electric vehicle and the apparatus therefor.

Furthermore, the present technology may provide the battery pack imbalance diagnosis method capable of extracting real-time AC impedance for each frequency via signal processing for a voltage and current original signal input from the BMS (e.g., CAN-based voltage data or direct analog measurements) and diagnosing battery pack imbalance on a cell-by-cell basis based on the real part impedance of passive electrochemical impedance spectroscopy (PEIS) of an individual cell in the battery pack (e.g., detecting an abnormal rise in impedance at 10 Hz, 50 Hz, or 1 kHz, etc.).

Furthermore, the present technology may provide the method for diagnosing the imbalance of the battery pack based on the BMS signal processing impedance to perform battery pack imbalance diagnosis by using AC impedance information extracted via signal processing for the voltage and current original signal input from the BMS as one index (e.g., frequency-specific impedance magnitude) and obtain various pieces of information, such as a state of health (SOH) and a safety deviation (e.g., capacity fade, internal resistance rise, thermal anomalies, or voltage drift, etc.) in the battery module and the apparatus therefor.

Furthermore, the present technology may provide the method for diagnosing the imbalance of the battery pack based on the BMS signal processing impedance to apply a statistical technique based on the real part impedance of the PEIS, which is AC impedance extracted via BMS input signal processing even without having separate EIS equipment (e.g., laboratory-grade electrochemical impedance spectroscopy analyzers), to diagnose imbalance in the battery pack and the apparatus therefor (e.g., using median absolute deviation (MAD) to identify outlier cells).

Furthermore, the present technology may provide the technology for diagnosing the imbalance of the battery pack in real time based on the PEIS, which is more efficient in cost and has better reliability than an existing DC-based diagnostic scheme (e.g., voltage drop measurement under load) and an existing EIS-based diagnostic scheme (e.g., off-board frequency sweep tests in a service center).

Furthermore, the present technology may simultaneously apply a DC signal and an AC signal to ensure precision for battery pack imbalance diagnosis (e.g., applying a small-amplitude AC perturbation over the DC operating current to improve measurement accuracy).

In addition, various effects ascertained directly or indirectly through the present disclosure may be provided.

Hereinabove, although the present disclosure has been described with reference to examples and the accompanying drawings, the present disclosure is not limited thereto, but may be variously modified and altered by those skilled in the art to which the present disclosure pertains without departing from the spirit and scope of the present disclosure claimed in the following claims.

Accordingly, examples of the present disclosure are intended not to limit but to explain the technical idea of the present disclosure, and the scope and spirit of the invention is not limited by the above examples. The scope of the present disclosure should be construed on the basis of the accompanying claims, and all the technical ideas within the scope equivalent to the claims should be included in the scope of the present disclosure.

What is claimed is:

1. A method performed by an apparatus for a vehicle, the method comprising:
obtaining, via one or more sensors, current and voltage signals associated with a battery pack of the vehicle;
processing the obtained current and voltage signals;
extracting, based on the processing of the obtained current and voltage signals, passive electrochemical impedance spectroscopy (PEIS) data;
setting, based on the PEIS data, a threshold for imbalance cell diagnosis;
performing, based on the threshold, the imbalance cell diagnosis on an individual cell in the battery pack; and
outputting a signal indicating a result of the imbalance cell diagnosis on the individual cell.

2. The method of claim 1, wherein the processing of the obtained current and voltage signals comprises:
performing a discrete wavelet transform by removing noise from at least one signal of the obtained current and voltage signals and decomposing the noise removed signal for each frequency level to obtain a time domain signal, wherein at least one signal comprises a direct current signal; and
performing a short time Fourier transform by segmenting the time domain signal into segments to convert the time domain signal into a frequency domain signal.

3. The method of claim 1, wherein the PEIS data comprises alternating current (AC) impedance data for each frequency point in the PEIS data, wherein the method further comprises:
based on a statistical technique and real part impedance data in the AC impedance data, determining the threshold.

4. The method of claim 3, further comprising:
deriving, via the statistical technique, a median absolute deviation (MAD) as a median value of absolute differences, wherein each absolute difference is between an impedance value of a cell in a group of cells of the battery pack and a median impedance value of all cells in the group of cells.

5. The method of claim 4, wherein the threshold comprises a lower limit threshold and an upper limit threshold, wherein the method further comprises:
based on the median impedance value and the MAD, determining the lower limit threshold and the upper limit threshold.

6. The method of claim 4, wherein one value in the median impedance value is derived for each frequency point in the PEIS data and one value in each of the absolute differences and the MAD is derived for each cell for each frequency point in the PEIS data.

7. The method of claim 6, wherein the median impedance value is derived as a median of the real part impedance data of cells in the group for each frequency point in the PEIS data.

8. The method of claim 5, further comprising:
determining the lower limit threshold by subtracting, from the median impedance value, a value obtained by multiplying the MAD by a constant; and
determining the upper limit threshold by adding, to the median impedance value, the value obtained by multiplying the MAD by the constant.

9. The method of claim 1, wherein the outputting of the signal comprises:
generating a warning message based on at least one imbalance cell being detected as the result of the imbalance cell diagnosis.

10. The method of claim 9, wherein the warning message comprises:
group identification information corresponding to a group containing the at least one imbalance cell, and
cell identification information corresponding to the at least one imbalance cell.

11. An apparatus for a vehicle, the apparatus comprising:
a processor; and
a memory storing at least one instruction that, when executed by the processor communicating with the memory, is configured to cause the apparatus to:
obtain, via one or more sensors, current and voltage signals associated with a battery pack of the vehicle,
process the obtained current and voltage signals,
extract, based on the processing of the obtained current and voltage signals, passive electrochemical impedance spectroscopy (PEIS) data,
set, based on the PEIS data, a threshold for imbalance cell diagnosis,
perform, based on the threshold, the imbalance cell diagnosis on an individual cell in the battery pack, and
output a signal indicating a result of the imbalance cell diagnosis on the individual cell.

12. The apparatus of claim 11, wherein the at least one instruction, when executed by the processor communicating with the memory, is configured to cause the apparatus to:
perform a discrete wavelet transform by removing noise from at least one signal of the obtained current and voltage signals and decompose the noise removed signal for each frequency level to obtain a time domain signal; and
perform a short time Fourier transform by segmenting the time domain signal into segments to convert the time domain signal into a frequency domain signal.

13. The apparatus of claim 11, wherein the PEIS data comprises alternating current (AC) impedance data for each frequency point in the PEIS data, and
wherein the at least one instruction, when executed by the processor communicating with the memory, is configured to cause the apparatus to:
based on a statistical technique and real part impedance data in the AC impedance data, determine the threshold.

14. The apparatus of claim 13, wherein the at least one instruction, when executed by the processor communicating with the memory, is configured to cause the apparatus to:
via the statistical technique, derive a median absolute deviation (MAD) as a median value of absolute differences, wherein each absolute difference is between an impedance value of a cell in a group of cells of the battery pack and a median impedance value of all cells in the group of cells.

15. The apparatus of claim 14, wherein the threshold comprises a lower limit threshold and an upper limit threshold, and
wherein the at least one instruction, when executed by the processor communicating with the memory, is configured to cause the apparatus to:
based on the median impedance value and the MAD, determine the lower limit threshold and the upper limit threshold.

16. The apparatus of claim 14, wherein one value in the median impedance value is derived for each frequency point in the PEIS data and one value in each of the absolute differences and the MAD is derived for each cell for each frequency point in the PEIS data.

17. The apparatus of claim 16, wherein the median impedance value is derived as a median of the real part impedance data of cells in the group for each frequency point in the PEIS data.

18. A vehicle comprising:
a battery pack;
a processor; and
a memory storing at least one instruction that, when executed by the processor communicating with the memory, is configured to cause the vehicle to:
receive voltage and current signals associated with a plurality of battery cells in the battery pack,
process the voltage and current signals to remove noise and derive frequency-domain data associated with the plurality of battery cells,
obtain, based on the frequency-domain data, passive cell impedance data, wherein the passive cell impedance data comprises real part impedance values of the plurality of battery cells,
determine a median of the real part impedance values and a median of absolute deviations of the real part impedance values,
set, based on the median of the real part impedance values and the median of absolute deviations, a threshold range for identifying imbalance of at least one cell of the plurality of battery cells,
based on a real part impedance value of the at least one cell being outside the threshold range, identify the at least one cell as an imbalance cell, and
output a warning signal indicating information of the imbalance cell.

19. The vehicle of claim 18, wherein the at least one instruction, when executed by the processor communicating with the memory, is configured to cause the vehicle to determine the threshold range by:
determining an upper limit threshold by adding, to the median of the real part impedance values, a value obtained by multiplying the median of absolute deviations by a constant, and
determining a lower limit threshold by subtracting, from the median of the real part impedance values, the value obtained by multiplying the median of absolute deviations by the constant.

20. The vehicle of claim 18, wherein the at least one instruction, when executed by the processor communicating with the memory, is configured to cause the vehicle to include, in the warning signal:
group identification information corresponding to a group of cells containing the imbalance cell, and
cell identification information corresponding to the imbalance cell.
